(19) United States
(12) Patent Application Publication
(10) Pub. No.: US 2008/0290791 A1
(43) Pub. Date: Nov. 27, 2008

(54) WHITE LIGHT-EMITTING ORGANIC LIGHT EMITTING DIODE, METHOD OF PREPARING THE SAME AND DEPOSITION DEVICE FOR IN-LINE DEPOSITION SYSTEM

(75) Inventors: YOUNG-GU LEE, YONGIN-SI (KR); IN-SEO KEE, YONGIN-SI (KR); ICK-HWAN KO, YONGIN-SI (KR); HONG-SHIK SHIM, YONGIN-SI (KR)

Correspondence Address: CANTOR COLBURN, LLP, 20 Church Street, 22nd Floor, Hartford, CT, 06103, US

(73) Assignee: SAMSUNG ELECTRONICS CO., LTD., SUWON-SI (KR)

(21) Appl. No.: 11/932,197

(22) Filed: Oct. 31, 2007

(30) Foreign Application Priority Data
May 22, 2007 (KR) 10-2007-0049946

(51) Int. Cl. H01L 51/50; H01J 9/02; B05B 7/00

(52) U.S. Cl. 313/504; 445/24; 118/300

(57) ABSTRACT

A white light-emitting organic light emitting diode includes; a substrate, a first electrode disposed on the substrate, a second electrode disposed on the substrate and facing the first electrode, and an organic layer disposed between the first electrode and the second electrode, the organic layer including an emissive layer including a first emissive layer having a first light emitting material (“LEM”), a second emissive layer having a second LEM, a third emissive layer having a third LEM, a first mixed interface layer including at least a part of the first LEM and at least a part of the second LEM, and a second mixed interface layer including at least a part of the second LEM and at least a part of the third LEM, the first and the second mixed interface layers being interposed between the first and second emissive layers and the second and the third emissive layers, respectively.

A white light-emitting organic light emitting diode including a substrate, a first electrode disposed on the substrate, a second electrode disposed on the substrate, the second electrode faces the first electrode and an organic layer disposed between the first electrode and the second electrode, the organic layer comprising an emissive layer including a first emissive layer including a first light emitting material, a second emissive layer including a second light emitting material and a third emissive layer including a third light emitting material, wherein the emissive layer comprises at least one layer of a first mixed interface layer including at least a part of the first light emitting material and at least a part of the second light emitting material, the first mixed interface layer being interposed between the first emissive layer and the second emissive layer, and a second mixed interface layer including at least a part of the second light emitting material and at least a part of the third light emitting material, the second mixed interface layer being interposed between the second emissive layer and the third emissive layer.

This application claims priority to Korean Patent Application No. 10-2007-0049946, filed on May 22, 2007, and all the benefits accruing therefrom under 35 U.S.C. §119, the contents of which in its entirety are herein incorporated by reference.

### BACKGROUND OF THE INVENTION

1. Field of the Invention

The present invention relates to an organic light emitting diode (“OLED”), a method of preparing the same and a deposition device for an in-line deposition system, and more particularly, to a white light-emitting OLED including a mixed interface layer disposed between two emissive layers which emit different colors, a method of preparing the same and a deposition device for an in-line deposition system including a deposition chamber for forming an emissive layer having light emitting material-deposition sources having different colors.

2. Description of the Related Art

OLEDs, which are self-emitting devices, include advantages such as having wide viewing angles, excellent contrast and quick pixel response speeds, and thus have drawn a large amount of public interest. In addition, OLEDs require a low operating voltage, have an excellent response property and can realize various colors, and therefore, much research thereon has been previously carried out.

Typically, an OLED includes an anode/emissive layer/cathode structure. An OLED can also include various other structures, such as an anode/hole transport layer/emissive layer/cathode structure and an anode/hole transport layer/emissive layer/electron injection layer/cathode structure by interposing a hole injection layer, a hole transport layer and an electron injection layer between the anode and the emissive layer or between the emissive layer and the cathode. An example of an OLED is disclosed in Korean Patent Publication No. 2005-0040960. In such OLEDs, white light emission can be realized by stacking at least two emissive layers that can emit different colors.

However, an efficiency and a lifetime characteristic of conventional OLEDs do not meet desired standards. Accordingly, there is a need for improving the efficiency and the lifetime characteristic of OLEDs.

### BRIEF SUMMARY OF THE INVENTION

The present invention provides an organic light emitting diode (“OLED”) having a high efficiency and a long lifetime using a mixed interface layer interposed between two emissive layers emitting different colors of light, a method of preparing the OLED and a deposition device for an in-line deposition system used to prepare the OLED.

According to an exemplary embodiment of the present invention, there is provided a white light-emitting OLED including a substrate, a first electrode disposed on the substrate, a second electrode disposed on the substrate, the second electrode faces the first electrode and an organic layer disposed between the first electrode and the second electrode, the organic layer including an emissive layer comprising a first emissive layer including a first light emitting material, a second emissive layer including a second light emitting material and a third emissive layer including a third light emitting material, wherein the emissive layer comprises at least one layer of a first mixed interface layer including at least a part of the first light emitting material and at least a part of the second light emitting material, the first mixed interface layer being interposed between the first emissive layer and the second emissive layer, and a second mixed interface layer including at least a part of the second light emitting material and at least a part of the third light emitting material, the second mixed interface layer being interposed between the second emissive layer and the third emissive layer.

In an exemplary embodiment, the emissive layer in the OLED may include both the first mixed interface layer and the second mixed interface layer.

In an exemplary embodiment, the first emissive layer, the second emissive layer and the third emissive layer may emit different colors of light.

In an exemplary embodiment, the first electrode may be a hole injection electrode, the first emissive layer may be a blue emissive layer, the second emissive layer may be a green emissive layer and the third emissive layer may be a red emissive layer, wherein the first emissive layer, the second emissive layer and the third emissive layer may be sequentially stacked on the first electrode.

In an exemplary embodiment, the first light emitting material may include a first host and a first dopant, the second light emitting material may include a second host and a second dopant and the first mixed interface layer may include at least one of the first host and the first dopant and at least one of the second host and the second dopant.

In an exemplary embodiment, the first light emitting material and the second light emitting material may be uniformly mixed or may have a concentration gradient in the first mixed interface layer.

In exemplary embodiments, the second light emitting material may include a second host and a second dopant, and the third light emitting material may include a third host and a third dopant, the second mixed interface layer may include at least one of the second host and the second dopant and at least one of the third host and the third dopant.

In an exemplary embodiment, the second light emitting material and the third light emitting material may be uniformly mixed or may have a concentration gradient in the second mixed interface layer.

In an exemplary embodiment, the organic layer may further include at least one layer of a hole injection layer, a hole transport layer, a hole blocking layer, an electron transport layer and an electron injection layer.

According to another exemplary embodiment of the present invention, there is provided a method of preparing a white light-emitting OLED, the method including disposing a first electrode on a substrate, disposing a second electrode on the substrate, the second electrode faces the first electrode and disposing an organic layer including an emissive layer comprising a first emissive layer including a first light emitting material, a second emissive layer including a second light emitting material and a third emissive layer including a third light emitting material, wherein the emissive layer comprises at least one layer of a first mixed interface layer including at least a part of the first light emitting material and at least a part of the second light emitting material, the first mixed interface layer being interposed between the first emissive layer and the second emissive layer, and a second mixed interface layer including at least a part of the second light emitting material and at least a part of the third light emitting material, the second mixed interface layer being interposed between the second emissive layer and the third emissive layer.

In an exemplary embodiment of the method, the disposing an organic layer may be performed by deposition using cluster-type deposition equipment or a deposition device for an in-line deposition system. The deposition device for the in-line deposition system may include a deposition chamber for disposing an emissive layer comprising a first light emitting material-deposition source and a second light emitting material-deposition source, a second light emitting material-deposition source and a third light emitting material-deposition source, or a first light emitting material-deposition source, a second light emitting material-deposition source and a third light emitting material-deposition source.

In an exemplary embodiment, the disposing an organic layer may further include disposing at least one layer of a hole injection layer, a hole transport layer, a hole blocking layer, an electron transport layer and an electron injection layer.

According to another exemplary embodiment of the present invention, there is provided a deposition device for an in-line deposition system comprising a plurality of deposition chambers disposed substantially in parallel to each other, wherein the plurality of deposition chambers includes a deposition chamber for disposing an emissive layer including light emitting material-deposition sources having different colors.

In an exemplary embodiment, the deposition chamber for forming an emissive layer may include a first light emitting material-deposition source and a second light emitting material-deposition source, a second light emitting material-deposition source and a third light emitting material-deposition source, or a first light emitting material-deposition source, a second light emitting material-deposition source and a third light emitting material-deposition source. Here, the first light emitting material may be a blue light emitting material, the second light emitting material may be a green light emitting material and the third light emitting material may be a red light emitting material.

The white light-emitting OLED of the present invention includes a high efficiency and a long lifetime, and a productivity thereof can thereby be improved by using the method of preparing the white light-emitting OLED. Further, the deposition device for the in-line deposition system can be used to prepare the OLED of the present invention.

### BRIEF DESCRIPTION OF THE DRAWINGS

The above and other aspects, features and advantages of the present invention will become more apparent by describing in detail exemplary embodiments thereof with reference to the attached drawings, in which:

FIGS. 1 through 3 are cross-sectional schematic diagram views of exemplary embodiments of a white light-emitting organic light emitting diode (“OLED”) according to the present invention;

FIGS. 4A, 5A, 6A, 7A and 8A are schematic diagrams illustrating an exemplary embodiment of a process of forming an emissive layer in a white light-emitting OLED according to the present invention;

FIGS. 4B, 5B, 6B, 7B and 8B are cross-sectional schematic diagrams illustrating deposition results obtained according to the process illustrated in FIGS. 4A, 5A, 6A, 7A and 8A, respectively;

FIG. 9 illustrates an EL spectrum of a conventional white light-emitting OLED of the prior art;

FIG. 10 illustrates an EL spectrum of an exemplary embodiment of a white light-emitting OLED according to the present invention;

FIG. 11 is an EL intensity versus current density graph illustrating efficiency characteristics of a conventional white light-emitting OLED of the prior art and of an exemplary embodiment of a white light-emitting OLED according to the present invention; and

FIG. 12 is an L/Lₒ versus driving time graph illustrating lifetime characteristics of a conventional white light-emitting organic light emitting diode of the prior art and of an exemplary embodiment of a white light-emitting OLED according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will now be described more fully with reference to the accompanying drawings, in which exemplary embodiments of the invention are shown.

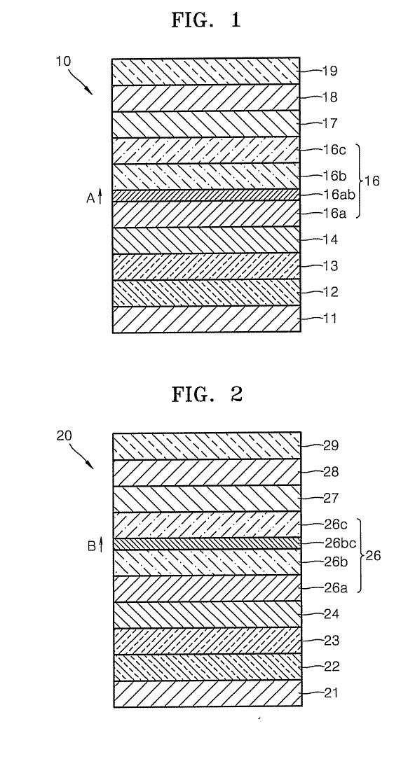

FIG. 1 is a cross-sectional schematic diagram view of an exemplary embodiment of a white light-emitting organic light emitting diode (“OLED”) 10 according to the present invention.

The white-emitting OLED 10 illustrated in FIG. 1 includes a substrate 11, a first electrode 12, a hole injection layer 13, a hole transport layer 14 and an emissive layer 16 which includes a first emissive layer 16a including a first light emitting material, a second emissive layer 16b including a second light emitting material and a third emissive layer 16c including a third light emitting material. A first mixed interface layer 16ab including at least a part of the first light emitting material and at least a part of the second light emitting material is interposed between the first emissive layer 16a and the second emissive layer 16b. An electron transport layer 17, an electron injection layer 18 and a second electrode 19 are sequentially formed on the emissive layer 16.

In exemplary embodiments, the substrate 11 illustrated in FIG. 1 may be any substrate which is used in a conventional OLED. In further exemplary embodiments, the substrate 11 may be a glass substrate or a transparent plastic substrate which includes excellent mechanical strength, thermal stability, transparency and surface smoothness, can be easily treated and is waterproof. A planarization layer, an insulating layer and the like may further be formed on the substrate 11 as desired, although they are not specifically shown in FIG. 1.

In exemplary embodiments, the first electrode 12 may be a transparent, semitransparent, or reflective electrode, and may be formed of indium tin oxide (“ITO”), indium zinc oxide (“IZO”), tin oxide (“SnO₂”), zinc oxide (“ZnO”), aluminum (Al), silver (Ag), magnesium (Mg), or the like. However, the present invention is not limited thereto. In alternative exemplary embodiments, the first electrode 12 may include a structure having at least two layers using at least two materials, and other structures. In further exemplary embodiments, the first electrode 12 may be used as a hole injection electrode (anode).

In exemplary embodiments, a hole injection layer 13 may be formed on the first electrode 12. In further exemplary embodiments, the hole injection layer 13 may be formed using vacuum deposition, spin coating, casting, Langmuir Blodgett (“LB”), or the like.

In exemplary embodiments, when the hole injection layer 13 is formed using vacuum deposition, vacuum deposition conditions may vary according to a compound which is used to form the hole injection layer 13 and desired structure and thermal properties of the hole injection layer 13 to be formed. In exemplary embodiments, for example, the vacuum deposition may be performed at a deposition temperature of about 100° C. to about 500° C., under a pressure of about 10⁻⁸ torr to about 10⁻³ torr, at a deposition speed of about 0.01 angstroms (Å)/second to about 100 Å/second.

In exemplary embodiments, when the hole injection layer 13 is formed using spin coating, coating conditions may vary according to a compound which is used to form the hole injection layer 13, and the desired structure and thermal properties of the hole injection layer 13 to be formed. In exemplary embodiments, for example, the coating speed may be in the range of about 2000 rpm to about 5000 rpm and a temperature for heat treatment, which is performed to remove a solvent after coating, may be in the range of about 80° C. to about 200° C.

In exemplary embodiments, the hole injection layer 13 may be formed of any material which is conventionally used to form a hole injection layer. Exemplary embodiments of the material include a phthalocyanine compound such as copper phthalocyanine, a star-burst type amine derivative such as 4,4′,4″-tri(N-carbazolyl)triphenylamine (“TCTA”) or 4,4′,4″-tris(3-methylphenylphenylamino)triphenylamine (“m-MTDATA”), a conductive polymer such as polyaniline/dodecyl benzenesulfonic acid (“Pani/DBSA”), poly 3,4-ethylenedioxythiophene/poly 4-styrenesulfonate (PEDOT/PSS), polyaniline/camphor sulfonic acid (Pani/CSA) or polyaniline/poly 4-styrene-sulfonate (PANI/PSS), or the like, however the material of the present invention is not limited thereto.

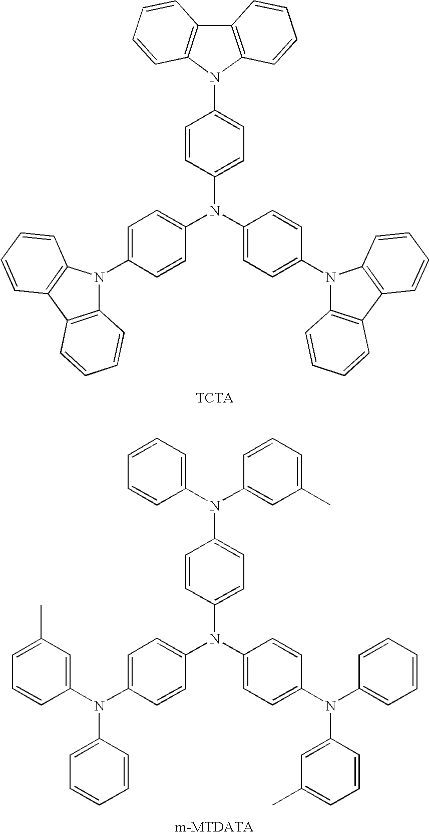

In exemplary embodiments, a thickness of the hole injection layer 13 may be in the range of about 10 nanometers (nm) to about 200 (nm). In an exemplary embodiment, the thickness of the hole injection layer is in the range of about 10 nm to about 100 nm. In further exemplary embodiments, the thickness of the hole injection layer 13 may vary within the range as described above in consideration of driving voltage properties, processing time and manufacturing costs.

In exemplary embodiments, a hole transport layer 14 may be formed on the hole injection layer 13. In further exemplary embodiments, the hole transport layer 14 may be formed using vacuum deposition, spin coating, casting, LB, or the like. In exemplary embodiment, when the hole transport layer 14 is formed using vacuum deposition or spin coating, conditions for deposition and coating may vary according to a compound which is used for the hole transport layer 14. In exemplary embodiments, for example, the conditions for deposition and coating are substantially similar to those for the formation of the hole injection layer 13, as discussed above.

In exemplary embodiments, the hole transport layer 14 may be formed of any material which is conventionally used to form a hole transport layer. Exemplary embodiments of the material include 1,3,5-tricarbazolylbenzene, 4,4′-biscarbazolylbiphenyl, polyvinylcarbazol, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (“TPD”), N,N′-di(naphthalene-1-il)-N,N′-diphenyl benzidine (“NPD”), N,N′-diphenyl-N,N′-bis(1-naphthyl)-(1,1′-biphenyl)-4,4′-diamine (“NPB”), poly(9,9-dioctylfluorene-co-N-(4-butylphenyl)diphenylamine) (“TFB”) and poly(9,9-dioctylfluorene-co-bis-(4-butylphenyl-bis-N,N-phenyl-1,4-phenylenediamin) (“PFB”), but the material of the present invention in not limited thereto.

In exemplary embodiments, the thickness of the hole transport layer 14 may be in the range of about 10 to about 200 nm. In an exemplary embodiment, the thickness of the hole transport layer 14 is in the range of about 10 nm to about 100 nm. In further exemplary embodiments, the thickness of the hole transport layer 14 may vary within the range as described above in consideration of driving voltage properties, processing time and manufacturing costs.

In exemplary embodiments, an emissive layer 16 is formed on the hole transport layer 14. The emissive layer 16 includes a first emissive layer 16a including a first light emitting material, a second emissive layer 16b including a second light emitting material and a third emissive layer 16c including a third light emitting material. A first mixed interface layer 16ab including at least one part of the first light emitting material and at least one part of the second light emitting material is interposed between the first emissive layer 16a and the second emissive layer 16b.

In exemplary embodiments, the first emissive layer 16a, the second emissive layer 16b and the third emissive layer 16c can emit different colors. In an exemplary embodiment, for example, if the first electrode 12 is formed to be a hole injection electrode which acts as an anode, the first emissive layer 16a may be a blue emissive layer, the second emissive layer 16b may be a green emissive layer and the third emissive layer 16c may be a red emissive layer, however the present invention is not limited thereto.

In exemplary embodiments, the first light emitting material, the second light emitting material and the third light emitting material may be selected among conventionally known light emitting materials. In exemplary embodiments, the first light emitting material, the second light emitting material and the third light emitting material may be selected among conventionally known light emitting materials to emit white light.

In exemplary embodiments, the first light emitting material, the second light emitting material and the third light emitting material may each be a single type of a light emitting material or may each be a combination of a host and a dopant. In an exemplary embodiment, for example, the first light emitting material may include a first host and a first dopant, and the second light emitting material may include a second host and a second dopant. In the current exemplary embodiment, the first mixed interface layer 16ab may include at least a part of the first light emitting material, e.g., include at least one of the first host and the first dopant, and the first mixed interface layer 16ab may include at least a part of the second light emitting material, e.g., may include at least one of the second host and the second dopant. That is, in exemplary embodiments, the first mixed interface layer 16ab may include, for example, the first host and the second host, or all of the first host, the first dopant, the second host and the second dopant.

In an exemplary embodiment, a conventionally known light emitting material, which can be used as the first light emitting material, the second light emitting material or the third light emitting material, may be tris (8-quinolinorate)aluminum (“Alq₃”), 4,4′-N,N′-dicarbazol-biphenyl (“CBP”), poly n-vinylcarbazol (“PVK”), bis (2-methyl-8-quinolinolato-N1,O8)-(1,1′-Biphenyl-4-olato)aluminum (“Balq”), or the like, however the present invention is not limited thereto. Meanwhile, in exemplary embodiments, materials which may be used as a host with known dopants will be described below.

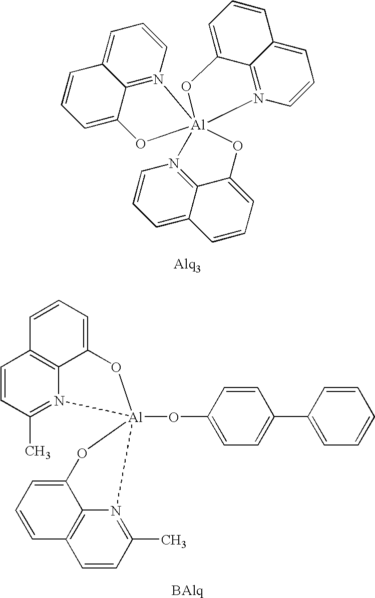

When the first light emitting material, the second light emitting material or the third light emitting material is to include a known red dopant, Pt(II) octaethylporphine (“PtOEP”), tris(1-phenylisoquinoline)iridium (III) (“Ir(piq)₃”), bis(3-(2-(2-pyridyl)benzothenoyl)mono-acetylacetonate iridium (III) (“Btp₂Ir(acac)”), 4-(dicyanomethylene)-2-t-butyl-6-(1,1,7,7-tetramethyljulolidyl-9-enyl)-4H-pyran (“DCJTB”), or the like may be used as the known red dopant, however the present invention is not limited thereto.

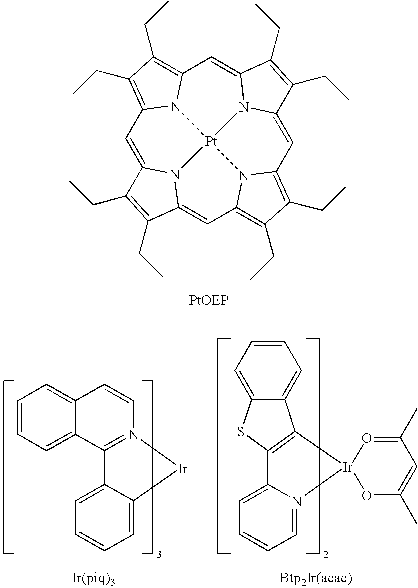

In addition, when the first light emitting material, the second light emitting material or the third light emitting material is to include a known green dopant, tris(2-phenylpyridine)iridium (III) (“Ir(ppy)₃”) (ppy=phenylpyridine), bis(4-methyl-(2-phenyl)pyridine)iridium (III) (“Ir(ppy)₂(acac)”), Ir(mpyp)₃, C545T, or the like may be used as the known green dopant, however the present invention is not limited thereto.

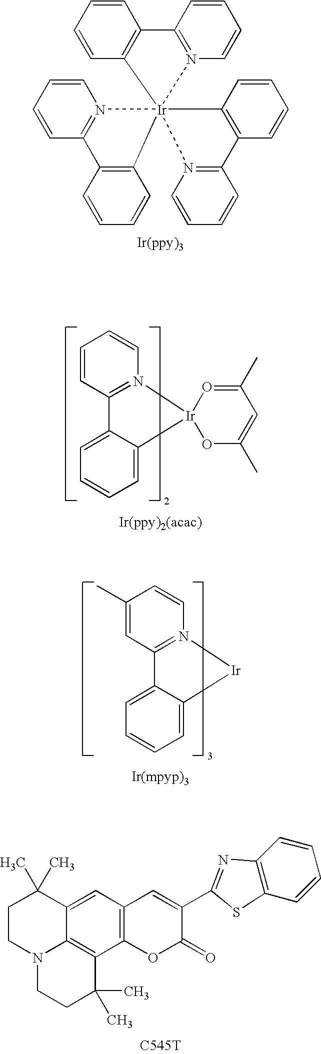

Meanwhile, when the first light emitting material, the second light emitting material or the third light emitting material is to include a known blue dopant, bis(3,5-Difluoro-2-(2-pyridyl)phenyl-(2-carboxypyridyl)iridium III (“F(Ir)pic”), (F₂ppy)₂Ir(tmd), Ir(dfppz)₃, ter-fluorene, or the like may be used as the known blue dopant, however the present invention is not limited thereto.

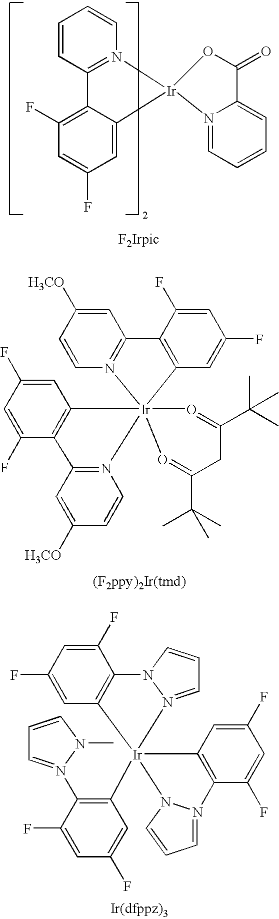

In exemplary embodiments, the concentration of the dopant may be in the range of about 0.1 to about 20 parts by weight. In an exemplary embodiment, the concentration of the dopant is about 0.5 to about 15 parts by weight based on 100 parts by weight parts of the total weight of the host and the dopant. When the concentration of the dopant is within the range as described above, concentration quenching, or the like does not occur.

Recombination of holes and electrons are effectively performed by including the first mixed interface layer 16ab, which includes at least a part of the first light emitting material and includes at least a part of the second light emitting material, disposed between the first emissive layer 16a and the second emissive layer 16b, and thus an exemplary embodiment of the white light-emitting OLED according to the present invention may have a high efficiency. Further, the first mixed interface layer 16ab may prevent or substantially reduce a deterioration of devices, and thus the white light-emitting OLED according to the present invention may have a long lifetime.

In exemplary embodiments, the first light emitting material and the second light emitting material may be uniformly mixed in the first mixed interface layer 16ab. In the current exemplary embodiment, a weight ratio between the first light emitting material and the second light emitting material may be in the range of about 10:1 to about 1:10. In an exemplary embodiment, the weight ratio between the first light emitting material and the second light emitting material is in the range of about 5:1 to about 1:5. In further exemplary embodiments, the weight ratio may be selected within the range as described above in consideration of thermal properties, energy levels and other properties of the first light emitting material and the second light emitting material.

In alternative exemplary embodiments, the first light emitting material and the second light emitting material may have a concentration gradient in the first mixed interface layer 16ab. Particularly, a concentration of the first light emitting material in the first mixed interface layer 16ab may gradually decrease in a direction from an interface between the first mixed interface layer 16ab and the first emissive layer 16a toward an interface between the first mixed interface layer 16ab and the second emissive layer 16b, e.g., in a direction “A” as shown in FIG. 1. Further, a concentration of the second light emitting material in the first mixed interface layer 16ab may gradually decrease in a direction from the interface between the first mixed interface layer 16ab and the second emissive layer 16b toward the interface between the first mixed interface layer 16ab and the first emissive layer 16a, e.g., in a direction opposite to the “A” direction as shown in FIG. 1.

In exemplary embodiments, the thickness of the first mixed interface layer 16ab may be in the range of about 1 nm to about 10 nm. In an exemplary embodiment, the thickness of the first mixed interface layer 16ab is in a range of about 2 nm to about 5 nm. When the thickness of the first mixed interface layer 16ab is within the above range, an efficiency and lifetime characteristics of the white light-emitting OLED may thereby increase without a substantial increase in driving voltage.

Meanwhile, the thickness of the first emissive layer 16a, the second emissive layer 16b and the third emissive layer 16c may each independently be in the range of about 1 nm to about 20 nm. In an exemplary embodiment, the thickness of the first emissive layer 16a, the second emissive layer 16b and the third emissive layer 16c are each in the range of about 5 nm to about 15 nm. When the thickness of the first emissive layer 16a, the second emissive layer 16b and the third emissive layer 16c is within the above range, an efficiency and lifetime characteristics of the white light-emitting OLED may thereby increase without a substantial increase in driving voltage.

Meanwhile, in exemplary embodiments, material which blocks holes may be formed using a vacuum deposition or a spin coating to prevent or substantially reduce a diffusion of triplet excitons or holes into an electron transport layer 17 when the phosphorescent dopant is used to form the emissive layer 16, although they are not specifically shown in FIG. 1. In exemplary embodiments, the hole blocking layer may be formed of, for example, an oxadiazole derivative, a triazole derivative, a phenanthroline derivative, or a hole blocking material as disclosed in JP 11-329734 A1, or 2,9-dimethyl-4,7-diphenyl-1,10-phenanthroline (“BCP”).

In exemplary embodiments, the electron transport layer 17 is formed on the emissive layer 16. In further exemplary embodiments, the electron transport layer 17 may be formed using vacuum deposition, spin coating, or the like. When the electron transport layer 17 is formed using vacuum deposition or spin coating, conditions for deposition and coating may vary according to a compound which is used to form the electron transport layer 17. In exemplary embodiments, for example, the conditions for deposition and coating are substantially similar to those for the formation of the hole injection layer 13.

In exemplary embodiments, the electron transport layer 17 may be formed of a quinoline derivative which stably transports electrons injected by a cathode, in particular tris(8-quinolinorate)aluminum (“Alq₃”), 3-(biphenyl-4-yl)-4-phenyl-5-(4-tert-butylphenyl)-1,2,4-triazole (“TAZ”), Balq, or the like, which is conventionally known in the art. The present invention, however, is not limited thereto.

In exemplary embodiments, a thickness of the electron transport layer 17 may be in the range of about 10 nm to about 100 nm. In an exemplary embodiment, the thickness of the electron transport layer 17 is in a range of about 10 nm to about 50 nm. In further exemplary embodiments, the thickness of the electron transport layer 17 may be selected within the range as described above in consideration of driving voltage properties, processing time and manufacturing costs.

In exemplary embodiments, an electron injection layer 18, which facilitates injection of electrons, is formed on the electron transport layer 17. In further exemplary embodiments, the electron injection layer 18 may be formed using vacuum deposition, spin coating, or the like. When the electron injection layer 18 is formed using vacuum deposition or spin coating, conditions for deposition and coating may vary according to a compound which is used to form the electron injection layer 18. In exemplary embodiments, for example, the conditions for deposition and coating are substantially similar to those for the formation of the hole injection layer 13. In exemplary embodiments, the electron injection layer 18 may be formed of a conventionally known material, such as lithium fluoride (“LiF”), sodium chloride (“NaCl”), cesium fluoride (“CsF”), lithium oxide (“Li₂O”), barium oxide (“BaO”), or the like. The present invention, however, is not limited thereto.

In exemplary embodiments, the thickness of the electron injection layer may be in the range of about 0.1 nm to about 10 nm. In an exemplary embodiment, the thickness of the electron injection layer is in a range of about 0.5 nm to about 2.0 nm. When the thickness of the electron injection layer is within the above range, excellent electron injecting properties and driving voltage properties may be obtained.

In exemplary embodiments, the second electrode 19 is formed on the electron injection layer 18. In further exemplary embodiments, the second electrode 19 may be formed using vacuum deposition, sputtering, or the like, and may be used as an electron injection electrode (cathode). In exemplary embodiments, the second electrode may be formed of a low work-function metal, an alloy, an electrically conductive compound, or a combination of thereof materials. In particular, the second electrode may be formed of lithium (Li), magnesium (Mg), aluminum (Al), aluminum-lithium (Al—Li), calcium (Ca), magnesium-indium (Mg—In), magnesium-silver (Mg—Ag), or the like. In alternative exemplary embodiments, the second electrode 28 may include a structure having at least two layers using at least two materials, or other structures.

FIG. 2 is a cross-sectional schematic diagram view of another exemplary embodiment of a white light-emitting OLED 20 according to the present invention. The white light-emitting OLED 20 illustrated in FIG. 2 includes a substrate 21, a first electrode 22, a hole injection layer 23, a hole transport layer 24 and an emissive layer 26, which includes a first emissive layer 26a including a first light emitting material, a second emissive layer 26b including a second light emitting material and a third emissive layer 26c including a third light emitting material. A second mixed interface layer 26bc including at least a part of the second light emitting material and at least a part of the third light emitting material is interposed between the second emissive layer 26b and the third emissive layer 26c. An electron transport layer 27, an electron injection layer 28 and a second electrode 29 are sequentially formed on the emissive layer 26. With regard to FIG. 2, the substrate 21, the first electrode 22, the hole injection layer 23, the hole transport layer 24, the first emissive layer 26a, the second emissive layer 26b, the third emissive layer 26c, the electron transport layer 27, the electron injection layer 28 and the second electrode 29 are all the same as described with respect to FIG. 1.

In FIG. 2, the second mixed interface layer 26bc includes at least a part of the second light emitting material and at least a part of the third light emitting material. In an exemplary embodiment, when the second light emitting material includes a second host and a second dopant, and the third light emitting material includes a third host and a third dopant, the second mixed interface layer 26bc may include at least a part of the second light emitting material, e.g., at least one of the second host and the second dopant, and at least a part of the third light emitting material, e.g., at least one of the third host and the third dopant. That is, in an exemplary embodiment, the second mixed interface layer 26bc may include, for example, the second host and the third host, or all of the second host, the second dopant, the third host and the third dopant, or any other possible variations.

In exemplary embodiments, recombination of holes and electrons are effectively performed by including the second mixed interface layer 26bc having at least a part of the second light emitting material and at least a part of the third light emitting material disposed between the second emissive layer 26b and the third emissive layer 26c, and thus the white light-emitting OLED may have a high efficiency. In further exemplary embodiments, the second mixed interface layer 26bc may prevent or substantially reduce a deterioration of devices, and thus the white light-emitting OLED may have a long lifetime.

In exemplary embodiments, the second light emitting material and the third light emitting material may be uniformly mixed in the second mixed interface layer 26bc. In the current exemplary embodiment, a weight ratio between the second light emitting material and the third light emitting material may be in the range of about 10:1 to about 1:10. In an exemplary embodiment, the weight ratio between the second light emitting material and the third light emitting material is in the range of about 5:1 to about 1:5. In further exemplary embodiments, the weight ratio may be selected within the range as described above in consideration of thermal properties, energy levels and other properties of the second light emitting material and the third light emitting material.

In exemplary embodiments, the second light emitting material and the third light emitting material may have a concentration gradient in the second mixed interface layer 26bc. Particularly, a concentration of the second light emitting material in the second mixed interface layer 26bc may gradually decrease in a direction from an interface between the second mixed interface layer 26bc and the second emissive layer 26b toward an interface between the second mixed interface layer 26bc and the third emissive layer 26c, e.g., in a direction “B” as shown in FIG. 2. Further, the concentration of the third light emitting material in the second mixed interface layer 26bc may gradually decrease in a direction from the interface between the second mixed interface layer 26bc and the third emissive layer 26c toward the interface between the second mixed interface layer 26bc and the second emissive layer 26b, e.g., in a direction opposite to the “B” direction as shown in FIG. 2.

In exemplary embodiments, the thickness of the second mixed interface layer 26bc may be in the range of about 1 nm to about 10 nm. In an exemplary embodiment, the thickness of the second mixed interface layer 26bc is in the range of about 2 nm to about 5 nm. When the thickness of the second mixed interface layer 26bc is within the above range, an efficiency and lifetime characteristics may thereby increase without a substantial increase in driving voltage.

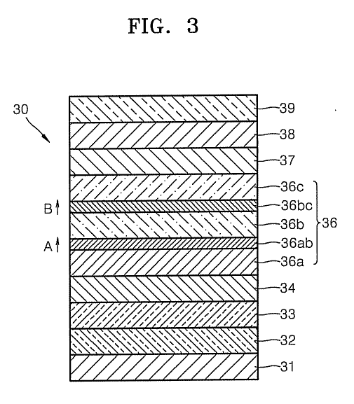

FIG. 3 is a cross-sectional schematic diagram view of another exemplary embodiment of a white light-emitting OLED 30 according to the present invention. The white light-emitting OLED 30 illustrated in FIG. 3 includes a substrate 31, a first electrode 32, a hole injection layer 33, a hole transport layer 34, and an emissive layer 36 which includes a first emissive layer 36a including a first light emitting material, a second emissive layer 36b including a second light emitting material and a third emissive layer 36c including a third light emitting material. The first mixed interface layer 36ab including at least a part of the first light emitting material and at least a part of the second light emitting material is interposed between the first emissive layer 36a and the second emissive layer 36b. The second mixed interface layer 36bc including at least a part of the second light emitting material and at least a part of the third light emitting material is interposed between the second emissive layer 36b and the third emissive layer 36c. An electron transport layer 37, an electron injection layer 38 and a second electrode 39 are sequentially formed on the emissive layer 36.

Each of the layers of the white light-emitting OLED 30 as shown in FIG. 3 have been described with respect to the previous exemplary embodiments.

The white light-emitting OLEDs according to exemplary embodiments of the present invention have been described with respect to FIGS. 1 through 3, however the present invention is not limited thereto. The present invention may, however, be embodied in many different forms. For example, the hole injection layer may or may not be omitted, as desired.

An exemplary embodiment of a method of preparing a white light-emitting OLED according to the present invention includes forming or disposing a first electrode on a substrate, forming an organic layer comprising an emissive layer which includes a first emissive layer including a first light emitting material, a second emissive layer including a second light emitting material and a third emissive layer including a third light emitting material, wherein the emissive layer includes at least one layer of a first mixed interface layer including at least a part of the first light emitting material and at least a part of the second light emitting material being interposed between the first emissive layer and the second emissive layer and a second mixed interface layer including at least a part of the second light emitting material and at least a part of the third light emitting material being interposed between the second emissive layer and the third emissive layer and forming or disposing a second electrode on the organic layer.

In exemplary embodiments, the forming of the organic layer may further include preparing at least one layer selected from the group consisting of a hole injection layer, a hole transport layer, a hole blocking layer, an electron transport layer and an electron injection layer.

In exemplary embodiments, the forming of the organic layer may be performed by deposition, coating, or the like.

In an exemplary embodiment, when the forming of the organic layer is performed by deposition, cluster-type deposition equipment or a deposition device for in-line deposition system and other devices may be used, however the present invention is not limited thereto.

Particularly, when the forming of the organic layer is performed using the deposition device for an in-line deposition system, a deposition chamber for forming an emissive layer included in the deposition device for the in-line deposition system may include a first light emitting material-deposition source and a second light emitting material-deposition source, a second light emitting material-deposition source and a third light emitting material-deposition source; or a first light emitting material-deposition source, a second light emitting material-deposition source and a third light emitting material-deposition source. An exemplary embodiment of a white light-emitting OLED according to the present invention, particularly a white light-emitting OLED in which at least two materials are used to form a mixed interface layer having a concentration gradient, can be easily prepared using the deposition device for the in-line deposition system including the deposition chamber for forming an emissive layer.

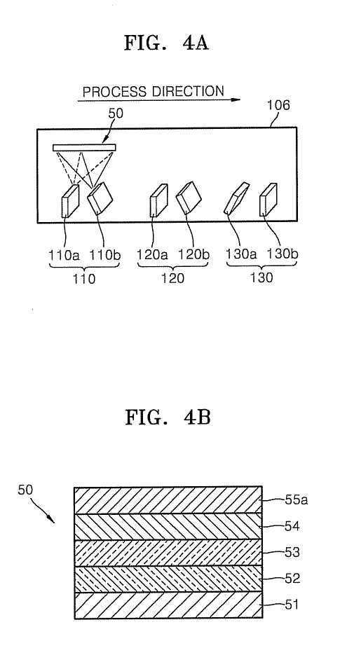

FIGS. 4A, 5A, 6A, 7A and 8A schematically show an exemplary embodiment of a process of forming an emissive layer of a white light-emitting OLED according to the present invention in the deposition chamber for forming an emissive layer 106 of the deposition device for in-line deposition system, and FIGS. 4B, 5B, 6B, 7B and 8B schematically illustrate deposition results obtained according to the processes illustrated in FIGS. 4A, 5A, 6A, 7A and 8A, respectively. In the deposition chamber for forming an emissive layer 106 illustrated in FIGS.4A, 5A, 6A, 7A and 8A deposition sources and substrates for forming the OLED are schematically illustrated. A substrate transport means, a deposition source isolating means and other means may be obvious to persons of ordinary skill in the art with reference to known technologies in the art, for example, those disclosed in Korean Patent Publication Nos. 2007-0045527 and 2005-0038121. The deposition chamber for forming an emissive layer 106 in FIGS. 4A, 5A, 6A, 7A and 8A includes a first host deposition source 110a and a first dopant deposition source 110b as the first light emitting material-deposition source 110, a second host deposition source 120a and a second dopant deposition source 120b as the second light emitting material-deposition source 120 and a third host deposition source 130a and a third dopant deposition source 130b as the third light emitting material-deposition source 130. Meanwhile, the substrate for forming the OLED 50 is transferred along a process direction as shown in FIGS. 4A, 5A, 6A, 7A and 8A.

First, the substrate for forming the OLED 50 including a first electrode 52, a hole injection layer 53 and a hole transport layer 54, which are formed on an upper portion of a substrate 51, is transferred to the deposition chamber for forming an emissive layer 106, as illustrated in FIG. 4A. Then, a first emissive layer 55a is formed on the hole transport layer 54 by heating the first light emitting material-deposition source 110 as illustrated in FIG. 4B.

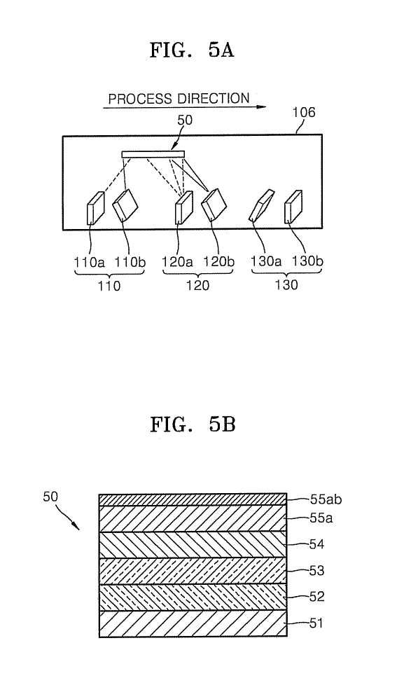

Then, the substrate for forming the OLED 50 is transferred to a position illustrated in FIG. 5A in a chamber for forming an emissive layer 106. Here, a first mixed interface layer 55ab including at least a part of the first light emitting material and at least a part of the second light emitting material is formed on the first emissive layer 55a, as illustrated in FIG. 5B, by heating at least a part of the first light emitting material-deposition source 110, e.g., at least one of the first host deposition source 110a and the first dopant deposition source 110b and by heating at least a part of the second light emitting material-deposition source 120, e.g., at least one of the second host deposition source 120a and the second dopant deposition source 120b.

Here, the mixing conditions of the first light emitting material and the second light emitting material in the first mixed interface layer 55ab can vary in exemplary embodiments. That is, the materials can be uniformly mixed or have a concentration gradient by controlling an arrangement and heating time of the first host deposition source 110a, the first dopant deposition source 110b, the second host deposition source 120a and the second dopant deposition source 120b, and a transfer speed of the substrate for forming the OLED 50, etc. In an exemplary embodiment, when the substrate for forming the OLED 50 is transferred at a constant speed, the first light emitting material and the second light emitting material in the first mixed interface layer 55ab may have a concentration gradient as described above.

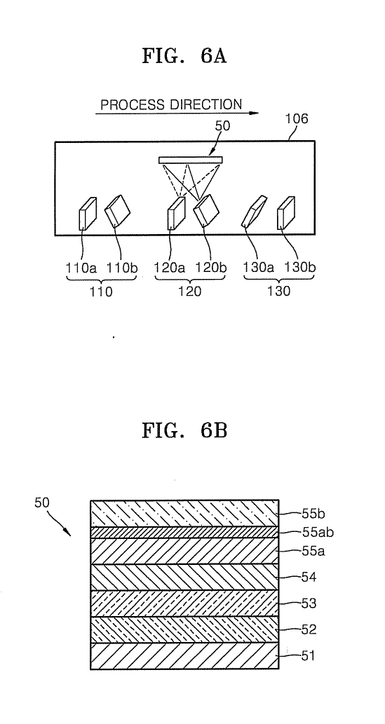

Then, the substrate for forming the OLED 50 is transferred to a position illustrated in FIG. 6A in a chamber for forming an emissive layer 106. Here, a second emissive layer 55b is formed on the first mixed interface layer 55ab by heating the second light emitting material-deposition source 120, as illustrated in FIG. 6B.

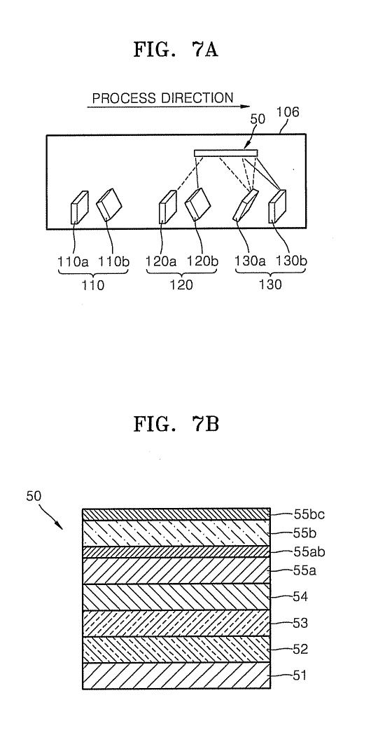

Then, the substrate for forming the OLED 50 is transferred to a position illustrated in FIG. 7A in a chamber for forming an emissive layer 106. Here, the second mixed interface layer 55bc including at least a part of the second light emitting material and at least a part of the third light emitting material is formed, as illustrated in FIG. 7B, by heating at least a part of the second light emitting material-deposition source 120, e.g., at least one of the second host deposition source 120a and the second dopant deposition source 120b, and by heating at least a part of the third light emitting material-deposition source 130, e.g., at least one of the third host deposition source 130a and the third dopant deposition source 130b.

Here, the mixing conditions of the second light emitting material and the third light emitting material in the second mixed interface layer 55bc may vary in exemplary embodiments. That is, the materials can be uniformly mixed or have a concentration gradient by controlling an arrangement and a heating time of the second host deposition source 120a, the second dopant deposition source 120b, the third host deposition source 130a and the third dopant deposition source 130b, and a transfer speed of the substrate for forming the OLED 50.

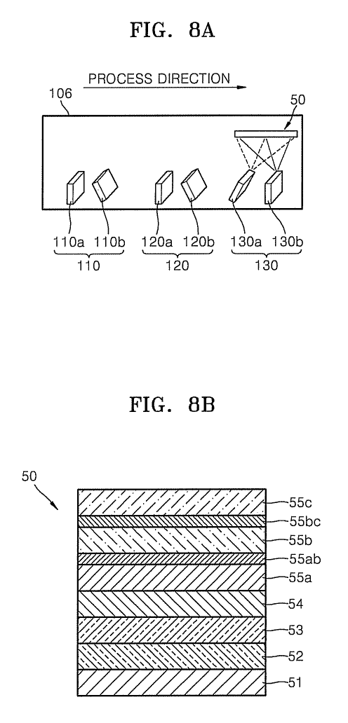

Then, the substrate for forming the OLED 50 is transferred to a position illustrated in FIG. 8A in a chamber for forming an emissive layer 106. Here, a third emissive layer 55c is formed by heating the third light emitting material-deposition source 130, as illustrated in FIG. 8B.

In the current exemplary embodiment, the first light emitting material may be a blue light emitting material, the second light emitting material may be a green light emitting material and the third light emitting material may be a red light emitting material, however the present invention is not limited thereto.

In exemplary embodiments, utilization of the deposition chamber for forming an emissive layer as described above may shorten a tack time as compared to a utilization of individual deposition chambers for each color, and thus a productivity can thereby be improved. In addition, use of a deposition device for an in-line deposition system including the deposition chamber for forming an emissive layer as described above may also allow the materials forming the first mixed interface layer and/or the second mixed interface layer to have a concentration gradient. Further, the first emissive layer, the first mixed interface layer, the second emissive layer, the second mixed interface layer and/or the third emissive layer are formed using a single deposition chamber for forming an emissive layer, and thus impurities, such as moisture, may be eliminated or substantially reduced from being included between adjacent layers. Accordingly, a decrease in efficiency and a reduction in lifetime are prevented, and thus a relative high quality white light-emitting OLED can be obtained.

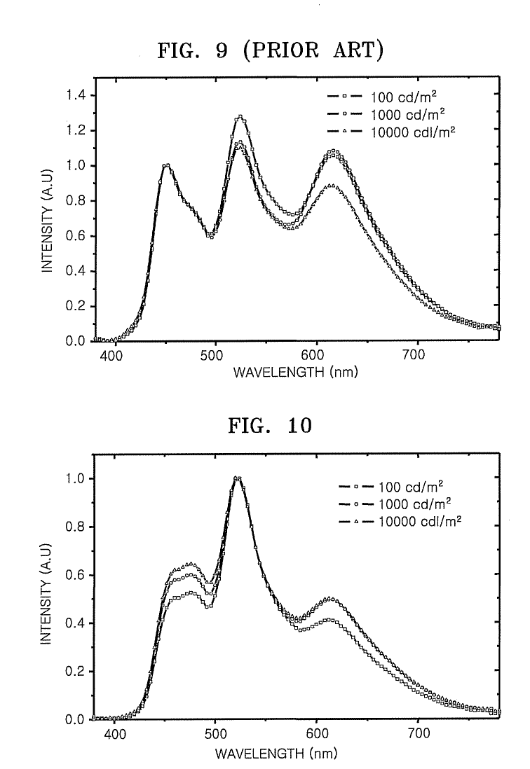

FIG. 9 illustrates an EL spectrum of an OLED of the prior art including an ITO layer with a thickness of less than 1500 Å as a first electrode, a NPB layer with a thickness of 800 Å as a hole transport layer, a first emissive layer with a thickness of 100 Å including a known blue host and 5 wt % of a blue dopant, a second emissive layer with a thickness of 90 Å including Alq₃ as a green host and 2 wt % of C545T as a green dopant, a third emissive layer with a thickness of 90 Å including Balq as a red host and 8 wt % of Btp2Ir(acac) as a red dopant, an Alq₃ layer with a thickness of 300 Å as an electron transport layer, a LiF layer with a thickness of 10 Å as an electron injection layer and an aluminum (Al) layer with a thickness of 1500 Å as a second electrode (Sample 1). FIG. 10 illustrates an EL spectrum of an OLED having a substantially similar structure as Sample 1, except that a first mixed interface layer, with a thickness of 20 Å and including the blue host included in the first emissive layer and the green host included in the second emissive layer, is included between the first emissive layer and the second emissive layer, and a second mixed interface layer, with a thickness of 20 Å and including the green host included in the second emissive layer and the red host included in the third emissive layer, is included between the second emissive layer and the third emissive layer are further included (Sample 2). The organic layers of Samples 1 and 2 are formed using a thermal deposition in a vacuum of about 10⁻⁶ torr. According to FIGS. 9 and 10, Samples 1 and 2 can emit a white light.

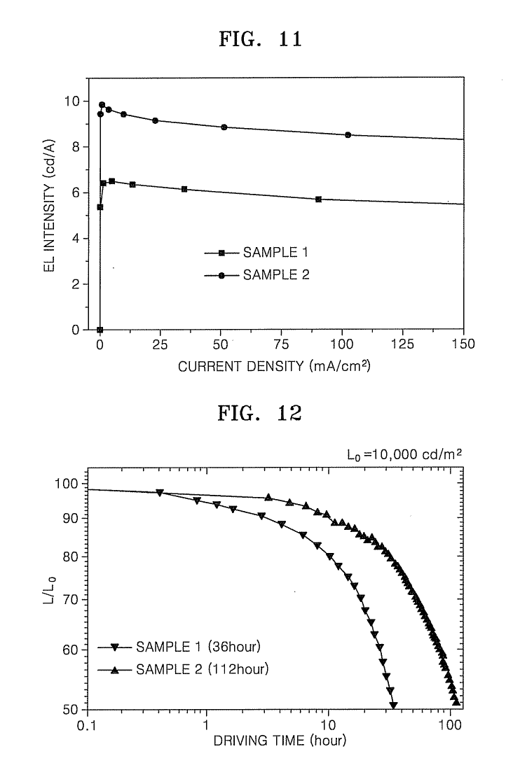

FIG. 11 is a graph illustrating efficiency characteristics of Samples 1 and 2. The efficiency characteristics of Samples 1 and 2 were measured using a PR650 spectroradiometer manufactured by Photo Research, Inc. According to FIG. 10, Sample 2 according to an exemplary embodiment of the present invention has about 1.5 times improved efficiency as compared to that of Sample 1.

FIG. 12 shows a graph illustrating lifetime characteristics of Samples 1 and 2. Lifetime characteristics of Samples 1 and 2 were evaluated by measuring a time of decrease in brightness to half its initial value obtained using a silicon (Si) photodiode. That is, each Sample 1 and 2 began with an initial luminance value (“Lₒ”) of 10,000 candela per square meter (cd/m²). Subsequently, a driving time was measured when each Sample 1 and 2 emitted 5,000 (cd/m²). According to FIG. 12, the lifetime of Sample 2 according to an exemplary embodiment of the present invention was about 3 times longer than that of Sample 1.

Therefore, the OLED according to the present invention has a higher efficiency and a longer lifetime as compared to conventional OLEDs.

The OLED according to the present invention may have excellent efficiency and a long lifetime by including mixed interface layers disposed between two emissive layers emitting different colors. In addition, a productivity can also be improved by the method of preparing the OLED according to the present invention.

While the present invention has been particularly shown and described with reference to some exemplary embodiments thereof, it will be understood by those of ordinary skill in the art that various changes in form and details may be made therein without departing from the spirit and scope of the present invention as defined by the following claims.

What is claimed is:

1. A white light-emitting organic light emitting diode comprising:
a substrate;
a first electrode disposed on the substrate;
a second electrode disposed on the substrate, the second electrode faces the first electrode; and
an organic layer disposed between the first electrode and the second electrode, the organic layer comprising an emissive layer comprising:
a first emissive layer including a first light emitting material;
a second emissive layer including a second light emitting material; and
a third emissive layer including a third light emitting material,
wherein the emissive layer comprises at least one layer of a first mixed interface layer including at least a part of the first light emitting material and at least a part of the second light emitting material, the first mixed interface layer being interposed between the first emissive layer and the second emissive layer, and a second mixed interface layer including at least a part of the second light emitting material and at least a part of the third light emitting material, the second mixed interface layer being interposed between the second emissive layer and the third emissive layer.

2. The white light-emitting organic light emitting diode of claim 1, wherein the emissive layer comprises both the first mixed interface layer and the second mixed interface layer.

3. The white light-emitting organic light emitting diode of claim 1, wherein the first emissive layer, the second emissive layer and the third emissive layer emit different colors of light.

4. The white light-emitting organic light emitting diode of claim 1, wherein the first electrode is a hole injection electrode, the first emissive layer is a blue emissive layer, the second emissive layer is a green emissive layer and the third emissive layer is a red emissive layer, wherein the first emissive layer, the second emissive layer and the third emissive layer are sequentially stacked on the first electrode.

5. The white light-emitting organic light emitting diode of claim 1, wherein the first light emitting material comprises a first host and a first dopant, the second light emitting material comprises a second host and a second dopant, and the first mixed interface layer comprises at least one of the first host and the first dopant and at least one of the second host and the second dopant.

6. The white light-emitting organic light emitting diode of claim 1, wherein the first light emitting material and the second light emitting material are uniformly mixed in the first mixed interface layer.

7. The white light-emitting organic light emitting diode of claim 1, wherein a concentration of the first light emitting material in the first mixed interface layer gradually decreases in a direction from an interface between the first mixed interface layer and the first emissive layer toward an interface between the first mixed interface layer and the second emissive layer, and a concentration of the second light emitting material in the first mixed interface layer gradually decreases in a direction from the interface between the first mixed interface layer and the second emissive layer toward the interface between the first mixed interface layer and the first emissive layer.

8. The white light-emitting organic light emitting diode of claim 1, wherein a thickness of the first mixed interface layer is in a range of about 1 nm to about 10 nm.

9. The white light-emitting organic light emitting diode of claim 1, wherein when the second light emitting material comprises a second host and a second dopant, and the third light emitting material comprises a third host and a third dopant, the second mixed interface layer comprises at least one of the second host and the second dopant and at least one of the third host and the third dopant.

10. The white light-emitting organic light emitting diode of claim 1, wherein the second light emitting material and the third light emitting material are uniformly mixed in the second mixed interface layer.

11. The white light-emitting organic light emitting diode of claim 1, wherein a concentration of the second light emitting material in the second mixed interface layer gradually decreases in a direction from an interface between the second mixed interface layer and the second emissive layer toward an interface between the second mixed interface layer and the third emissive layer, and a concentration of the third light emitting material in the second mixed interface layer gradually decreases in a direction from the interface between the second mixed interface layer and the third emissive layer toward the interface between the second mixed interface layer and the second emissive layer.

12. The white light-emitting organic light emitting diode of claim 1, wherein a thickness of the second mixed interface layer is in a range of about 1 nm to about 10 nm.

13. The white light-emitting organic light emitting diode of claim 1, wherein the organic layer further comprises at least one layer of a hole injection layer, a hole transport layer, a hole blocking layer, an electron transport layer and an electron injection layer.

14. A method of preparing a white light-emitting organic light emitting diode, the method comprising:
disposing a first electrode on a substrate;
disposing a second electrode on the substrate, the second electrode facing the first electrode; and
disposing an organic layer between the first electrode and the second electrode, the organic layer comprising an emissive layer which comprises a first emissive layer including a first light emitting material, a second emissive layer including a second light emitting material and a third emissive layer including a third light emitting material, wherein the emissive layer comprises at least one layer of a first mixed interface layer including at least a part of the first light emitting material and at least a part of the second light emitting material, the first mixed interface layer being interposed between the first emissive layer and the second emissive layer, and a second mixed interface layer including at least a part of the second light emitting material and at least a part of the third light emitting material, the second mixed interface layer being interposed between the second emissive layer and the third emissive layer.

15. The method of claim 14, wherein the disposing of the organic layer is performed by deposition using cluster-type deposition apparatus or a deposition device for an in-line deposition system.

16. The method of claim 15, wherein the deposition device for the in-line deposition system comprises a deposition chamber for disposing an emissive layer comprising a first light emitting material-deposition source and a second light emitting material-deposition source, a second light emitting material-deposition source and a third light emitting material-deposition source, or a first light emitting material-deposition source, a second light emitting material-deposition source and a third light emitting material-deposition source.

17. The method of claim 16, wherein a plurality of sources in the deposition chamber for disposing an emissive layer is one of a point source, a point array source, a linear source, or a combination of thereof sources.

18. The method of claim 14, wherein the disposing of the organic layer further comprises disposing at least one layer of a hole injection layer, a hole transport layer, a hole blocking layer, an electron transport layer and an electron injection layer.

19. A deposition device for an in-line deposition system comprising:
a plurality of deposition chambers disposed substantially in parallel with each other, wherein the plurality of deposition chambers comprise a deposition chamber for disposing an emissive layer including light emitting material-deposition sources having different colors.

20. The deposition device for the in-line deposition system of claim 19, wherein the deposition chamber for disposing an emissive layer comprises a first light emitting material-deposition source and a second light emitting material-deposition source, a second light emitting material-deposition source and a third light emitting material-deposition source, or a first light emitting material-deposition source, a second light emitting material-deposition source and a third light emitting material-deposition source.
